(19) United States
(12) Patent Application Publication
(10) Pub. No.: US 2008/0018395 A1
(43) Pub. Date: Jan. 24, 2008

(54) Anti-pop circuit

(75) Inventors: Cheng-Jan Chi, Taipei (TW); Chung-Ta Chin, Taipei (TW); Wen-Cheng Ko, Taipei (TW); Yi-Hsuan Huang, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/822,089

(22) Filed: Jul. 2, 2007

(30) Foreign Application Priority Data
Jul. 5, 2006 (TW) 95124547

(51) Int. Cl. H03F 1/14

(52) U.S. Cl. 330/51

(57) ABSTRACT

The present invention provides an anti-pop circuit composed of a capacitor and a switch. A control signal is used to switch the switch to make the capacitor grounded. The grounded capacitor may shunt the “pop” sound at the moment the power (Vcc) is turned on or off.

### RELATED APPLICATIONS

This application claims priority to Taiwan Application Serial Number 95124547, filed Jul. 5, 2006, which is herein incorporated by reference.

### FIELD OF THE INVENTION

The present invention describes an anti-pop circuit, and more particularly, describes an anti-pop circuit with a capacitor.

### BACKGROUND OF THE INVENTION

FIG. 1 illustrates a typical audio output circuit 100. An electrostatic protection circuit 102 is used to shunt harmful external static electricity away from the audio output circuit 100. A sound signal from an audio IC or a speaker is outputted through a low-pass filter 104 and the electrostatic protection circuit 102.

However, a “pop” sound is always intermixed with the outputted sound signal the moment the power (Vcc) is turned on or off due to voltage spiking. Typically, an anti-pop circuit 106 is installed in the audio output circuit 100 to eliminate the “pop” sound.

FIG. 1 illustrates a typical anti-pop circuit 106 including two PNP type bipolar junction transistors (BJTs) 108 and 110. Before the power (Vcc) is turned on, a control signal triggers the anti-pop circuit 106 first to activate the BJT 110 to prevent the “pop” sound caused by the voltage spike from being mixed into the outputted voice signal.

Specifically, a control signal with a low voltage level is outputted first to turn off the BJT 108 so that a high voltage level is generated to turn on the BJT 110. Typically, a special time period to keep BJT 110 turned on is set, such as 10 ms, after which the power is considered stable and not prone to cause “pop” sounds from spiking. After the set time period is reached, the control signal is transferred from a low voltage level to a high voltage level to turn on the BJT 108 so as to generate a low voltage level to turn off the BJT 110. At this time, the anti-pop circuit 106 is turned off.

However, the typical anti-pop circuit 106 can not remove the “pop” sounds with negative polarity. For example, when a “pop” sound with negative polarity occurs, the base electrode voltage of the BJT 110 is larger than the voltage in the collector electrode. In such a voltage state, the base electrode and the collector electrode act as a diode to forbid the “pop” sound being lead out from the BJT 110. Moreover, in the prior art, the anti-pop circuit 106 is coupled to the main circuit through the BJT 110. Therefore, it is not impossible to absolutely separate the anti-pop circuit 106 and the main circuit. Therefore, the output sound signal is always affected by the anti-pop circuit 106 even though the anti-pop circuit 106 is stopped. Especially, when the output sound signal is a sine wave, the diode served by the base electrode and the collector electrode may cut the negative part of the sine wave to reduce the sound quality.

Accordingly, an anti-pop circuit may resolve the foregoing problem is required.

### SUMMARY OF THE INVENTION

Therefore, the main purpose of the present invention is to provide an anti-pop circuit to release the “pop” sounds no matter what polarity the “pop” sound has.

Accordingly, the present invention provides an anti-pop circuit composed of a capacitor and a switch. A control signal is used to switch the switch to ground the capacitor grounded. The grounded capacitor absorbs the “pop” sound generated when the power is turned on or turned off.

According to an embodiment, the anti-pop circuit includes a capacitor, a switch and a control circuit. The switch has two ends, wherein one end is coupled to the capacitor and the other end is grounded. The control circuit generates a control signal to switch the switch, wherein when the switch status is changed by the control signal, the “pop” sound is absorbed by the capacitor.

According to an embodiment, the anti-pop circuit includes a capacitor, a switch and a control circuit. The capacitor has two ends, wherein one end is coupled to the switch and the other end is grounded. The control circuit generates a control signal to switch the switch, wherein when the switch status is changed by the control signal, the “pop” sound is absorbed by the capacitor.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1 illustrates a typical diagram of a sound output apparatus with an anti-pop circuit;

FIG. 2 illustrates a diagram of a sound output apparatus with an anti-pop circuit according to the first embodiment of the present invention;

FIG. 3 illustrates a diagram of a sound output apparatus with an anti-pop circuit according to the second embodiment of the present invention;

FIG. 4 illustrates a detailed circuit of an anti-pop circuit according to an embodiment of the present invention; and

FIG. 5 illustrates a flow chart for operating an anti-pop circuit according to an embodiment of the present invention;

### DETAILED DESCRIPTION OF THE PREFERRED EMBODIMENT

FIG. 2 is a sound output apparatus according to the first embodiment of the present invention. The sound output apparatus 209 includes a low-pass filter 201, an output circuit 203 and an anti-pop circuit 205. The anti-pop circuit 205 includes a control circuit 2051, a switch 2052 and a capacitor 2053.

When the power (Vcc) is turned on or turned off, one end of the capacitor 2053 is grounded to avoid the “pop” phenomenon. According to this embodiment, before the power (Vcc) is turned on, the control circuit 2051 may output a control signal to turn on the switch 2052 to ground the capacitor 2053. The grounded capacitor 2053 absorbs the pop sound coming from the power being turned on or turned off. Next, the control circuit 2051 may output another control signal to turn off the switch 2052 to place one end of the capacitor 2053 in a float state. At this time, the anti circuit 205 shuts down and a sound signal without a pop sound is outputted from the output circuit 203.

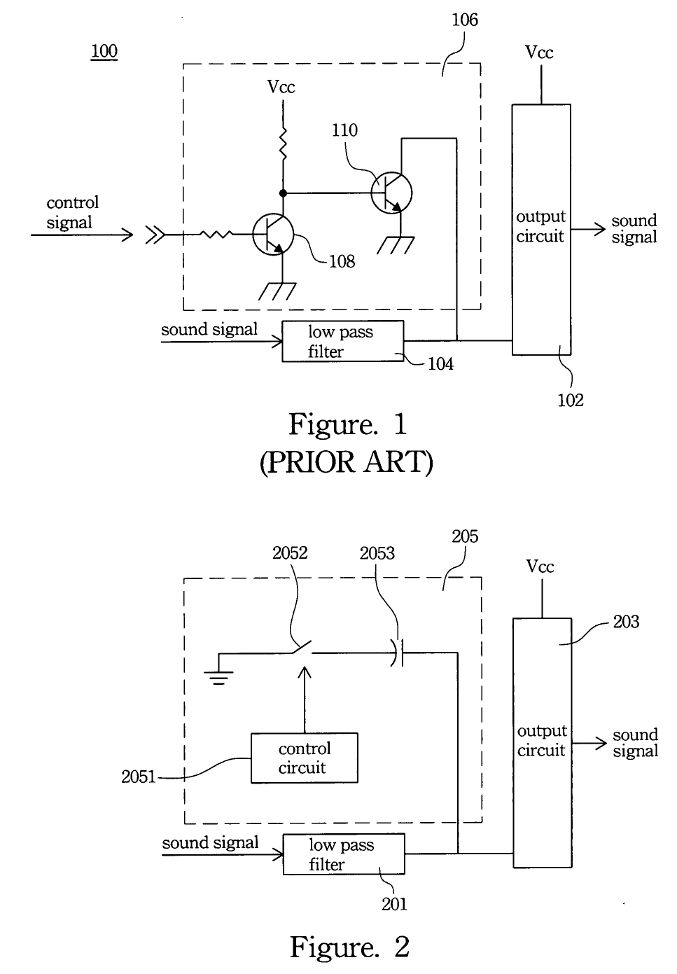

According to this embodiment, because of the inherent characteristic of a capacitor 2053, the pop sound with positive polarity and the pop sound with negative polarity both may be absorbed by the capacitor 2053. Therefore, the disadvantage of the prior art where a negative polarity pop sound cannot be absorbed is resolved. Moreover, in the present invention, the anti circuit 205 is shut down by floating one end of the capacitor 2053. When one end of the capacitor is in a floating state, the connection relationship between the anti circuit 205 and the output circuit 203 and the low pass filter is cut off. Because of the inherent characteristic of a capacitor 2053, the cut off efficiency of using the capacitor in the embodiment of the present invention is better than the cut off efficiency of using the BJT in the typical circuit as shown in the FIG. 1. In other words, even though the outputted sound signal is a sine wave, the phenomenon for cutting the wave does not occur. Therefore, a high quality sound signal is generated. On the other hand, the capacitor 2053 is coupled to the low pass filter 201. Therefore, when the control circuit 2051 conducts the switch 2052, the capacitor 2053 and a resistor of the low pass filter 201 may form another filter to further restrain the “pop” phenomenon.

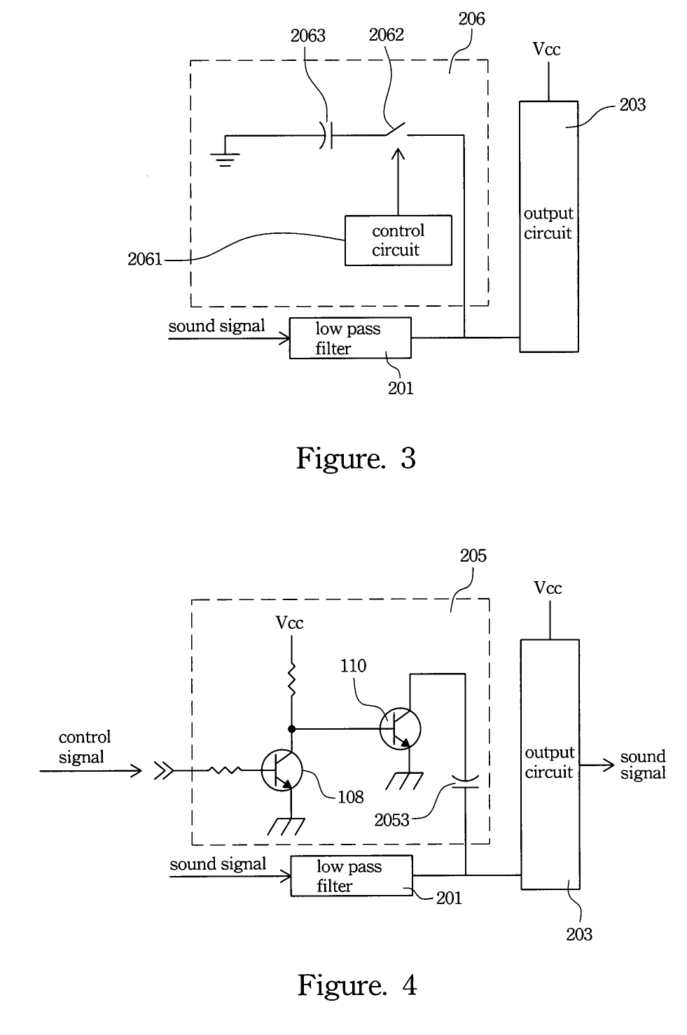

FIG. 3 illustrates another embodiment of an anti-pop circuit 306 of the present invention. According to this embodiment, before the power is turned on, the control circuit 2061 outputs a control signal to conduct the switch 2062 so as to absorb the popping sound generated at the moment of turning on the power from the switch 2062 to the capacitor 2063. Next, the control circuit 2061 may output a control signal to cut off the switch 2062 to place one end of the capacitor 2063 in a floating state. At this time, the anti-pop circuit 206 is stopped and a normal sound signal is outputted.

It is noticed that the control circuit 2051 and the switch 2052 also can use the typical circuit structure as shown in the FIG. 1. The circuit structure is illustrated in FIG. 4. A capacitor 2053 is installed between the BJT 110 and the main circuit. When the power (Vcc) is turned on, a control signal is set to a low voltage level to turn off the BJT 108. At this time, the power (Vcc) may turn on the BJT 110. Then, the “pop” sound generated at the moment of turning on or turning off the power is absorbed by the capacitor 2053. Because of the inherent characteristics of the capacitor 2053, the pop sound with negative polarity is absorbed by the capacitor 2053 too.

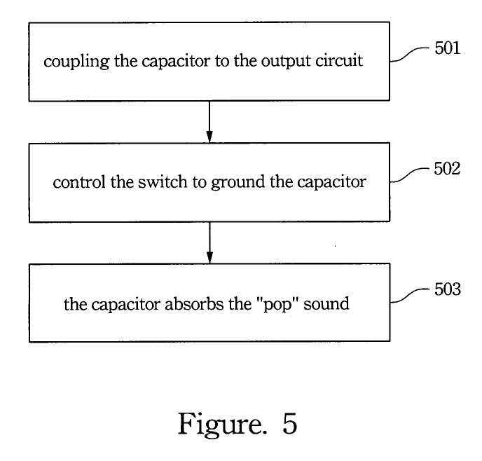

FIG. 5 illustrates a flow chart of operating this anti-pop circuit according to an embodiment of the present invention. Please refer to FIG. 2 and FIG. 5. It is noticed that this flow chart may also be used in for embodiments. In this embodiment, in step 501, a capacitor 2053 is first coupled to an output circuit 203. In step 502, before the power is turned on, the control circuit 2061 outputs a control signal to switch the switch 2052 to ground the capacitor 2053. Finally, in step 503, the popping sound generated at the moment of turning on the power is absorbed by the capacitor 2053.

Accordingly, the anti-pop circuit of the embodiment of the present invention includes a capacitor. Because of the inherent characteristic of a capacitor, the pop sound with positive polarity and the pop sound with negative polarity both may be absorbed by the capacitor. Therefore, the disadvantage of the prior art where a negative polarity pop sound cannot be absorbed is resolved. Moreover, the capacitor and a resistor of the low pass filter may form another filter to further restrain the “pop” phenomenon.

As is understood by a person skilled in the art, the foregoing descriptions of the preferred embodiments of the present invention are an illustration of the present invention rather than a limitation thereof. Various modifications and similar arrangements are included within the spirit and scope of the appended claims. The scope of the claims should be accorded to the broadest interpretation so as to encompass all such modifications and similar structures. While preferred embodiments of the invention have been illustrated and described, it will be appreciated that various changes can be made therein without departing from the spirit and scope of the invention.

What is claimed is:

1. An anti-pop circuit, wherein the circuit is coupled with a sound output device, comprising:
a capacitor coupled with the sound output device;
a switch with two ends, wherein one end is coupled to the capacitor and the other end is grounded; and
a control circuit to generate a control signal to switch the switch, wherein when the switch is conducted by the control signal, a “pop” sound is absorbed by the capacitor.

2. The anti-pop circuit of claim 1, wherein the switch comprises a BJT.

3. The anti-pop circuit of claim 1, wherein the control circuit comprises a BJT.

4. The anti-pop circuit of claim 1, wherein when the switch is cut off by the control signal, the anti-pop circuit is stopped.

5. An anti-pop circuit, wherein the circuit is coupled with a sound output device, comprising:
a switch coupling with the sound output device;
a capacitor with two ends, wherein one end is coupled to the switch and the other end is grounded; and
a control circuit to generate a control signal to switch the switch, wherein when the switch is conducted by the control signal, a “pop” sound is absorbed by the capacitor.

6. The anti-pop circuit of claim 5, wherein the switch comprises a BJT.

7. The anti-pop circuit of claim 5, wherein the control circuit comprises a BJT.

8. The anti-pop circuit of claim 5, wherein when the switch is cut off by the control signal, the anti-pop circuit is stopped.

9. A method to prevent a “pop” sound from a sound output device, comprises:
coupling a capacitor to the sound output device;
generating a control signal to switch a switch; and
when the switch is switched by the control signal, the “pop” sound is absorbed by the capacitor.

10. The method of claim 9, wherein coupling a capacitor to the sound output device is through at least one BJT.
